(19) United States
(12) Patent Application Publication
(10) Pub. No.: US 2016/0320324 A1
(43) Pub. Date: Nov. 3, 2016

(54) Method for Predicting the Life of Transformer based on Fiber Grating Temperature Measurement System

(71) Applicants: TAIYUAN POWER SUPPLY COMPANY OF STATE GRID SHANXI ELECTRIC POWER COMPANY, Taiyuan, Shanxi (CN); WUHAN NARI LIMITED LIABILITY COMPANY OF STATE GRID ELECTRIC POWER RESEARCH INSTITUTE, Wuhan, Hubei (CN); STATE GRID CORPORATION OF CHINA, Beijing (CN)

(72) Inventors: Junliu ZHANG, Wuhan (CN); Guohua ZHOU, Wuhan (CN); Lijuan XIONG, Wuhan (CN); Xin GAO, Wuhan (CN); Qiang XU, Wuhan (CN); Jiangong REN, Wuhan (CN); Shanshan WANG, Wuhan (CN); Siyuan LIANG, Wuhan (CN)

(21) Appl. No.: 14/901,716

(22) PCT Filed: Nov. 27, 2013
(86) PCT No.: PCT/CN2013/087933

§ 371 Date: Dec. 28, 2015

(30) Foreign Application Priority Data
Jun. 28, 2013 (CN) 201310267539.9

(51) Int. Cl. G01N 25/72; G01R 31/12

(52) U.S. Cl. CPC G01N 25/72; G01R 31/1227; G01K 11/3206

(57) ABSTRACT

A method for predicting the life of a transformer includes: conducting a quasi-distributed description on an internal temperature of a transformer by using a fiber grating temperature measurement system; determining the position of an internal hottest spot of the transformer and conducting a life evaluation on an internal local region of the transformer; and according to the life loss of each position of the transformer, by combining the insulation characteristic of the transformer with the influence of the life of the position on the entire life of the transformer, predicting the life of the transformer scientifically and reasonably. The method can use the fiber grating temperature measurement system to calculate and evaluate the life loss of the internal insulation of the transformer and the rate of change thereof

### NOTICE OF COPYRIGHT

A portion of the disclosure of this patent document contains material which is subject to copyright protection. The copyright owner has no objection to any reproduction by anyone of the patent disclosure, as it appears in the United States Patent and Trademark Office patent files or records, but otherwise reserves all copyright rights whatsoever.

### BACKGROUND OF THE PRESENT INVENTION

1. Field of Invention

The present invention relates to a field of on-line monitoring of a transformer of a power transmission equipment, and more particularly to a method for detecting the actual temperature inside a transformer by a fiber grating temperature measurement system, evaluating and predicting the insulation life of a transformer according to the insulation properties of the transformer.

2. Description of Related Arts

The internal temperature of a power transformer is an important parameter to represent the thermal characteristics of the transformer and is a key factor of an insulation life of the transformer. According to “GB 1094.7-2008 Power transformer—Part 7: guide rule for load of oil-immersed power transformers”, the life loss of the insulation of the transformer directly depends on the hottest temperature and the duration thereof during the operation process of the transformer. Since the transformer has a high voltage, high electromagnetic field environment at an inner side thereof, it is difficult or even impossible to obtain actual testing results through a traditional method of temperature measurement, so domestic and overseas scholars have carried out related researches long ago and achieved certain results. At present, there are mainly three methods to obtain the internal temperature of the transformer: a method of thermal simulation measurement, a method of indirect calculation and a method of direct measurement.

Thermal Simulation Measurement Method

The thermal simulation measurement method is based on a hot spot temperature of a winding: tₕ=KΔt_{w0}+t₀, wherein Δt_{w0} is a parameter which represents a temperature difference between copper and oil; tₒ is a parameter which represents a temperature of a top layer of the oil; K is a parameter which represents a hot spot coefficient. The test system obtains a value of a current L_{w} (proportional to the load) via a current transformer, the electric currents passes through a specially designed heating element in the bulb to obtain a value of Δt_{w0} , which plus a value of t₀ to obtain the hot spot temperature of the winding.

A premise of the thermal simulation method is the temperature of the top of the transformer oil tank, the top oil temperature in the winding and the oil temperature of the transformer being approximate to each other. It is not suitable for a transformer of a multi-line system. Although the parameter of additional temperature rising Δt_{w0} has been calibrated during simulation, the temperature rising process of the operating winding is different with the simulation. The error is relatively large. The French power grid has abandoned this temperature measuring device. After analyzing the measurement error of the thermal simulation method, it is found that to strictly design and select a suitable thermometer of the winding and a thermometer seat in the thermal simulation method is able to improve the temperature measurement performance of the thermal simulation method.

Indirect Calculation Method

The indirect calculation method, which is most widely used in the hot spot temperature calculation model, is recommended by IEEE Std C57.91 and IEC354 standards. In both models, the value of the hot-spot temperature is calculated based on the values of the ambient temperature, the top oil or base oil temperature and the temperature difference between hot spots of the winding and the oil. In the prediction equations, different load factors are used to correct different load conditions. For different types of cooling, the relative winding index and oil index are used to for correcting. However, there are often relatively large errors during calculating in empirical models, especially when the top oil temperature of a large-capacity transformer lags far behind the oil temperature of the winding. When the load of the transformer increases rapidly, due to the response speed of heat transferring, the top oil temperature of the transformer will reflect the changing of the winding conditions after a period of delay. In this condition, this method can hardly reflect the rapid temperature changes of the winding and interturn oil ducts. It hardly makes any sense to evaluate on the permitted overload and the operation life of the transformer.

Therefore, scholars have provided many improved hot spot temperature models based on these two prediction models. These kinds of model are improved based on the hot spot temperature model recommended by the above two standards. For example, when load increase is found by testing in different operating conditions of the transformer, the actual hot spot temperature of the winding of the transformer rises faster than the predicted value through the exponential equation adopting top oil time constant, so the equation recommended by the standards is amended, wherein a overshoot factor is introduced to the hot spot temperature rising coefficient. In addition, the recommended equation is further amended on the basis of a thermal experimental study of a short-circuit of the transformer. A hot spot predictive equation is established based on the base oil hot temperature. In 2001, Swift et al. of Manitoba University in Canada has provided a model for predicting the hot spot temperature based on the thermoelectric analogy. Such models contain many nonlinear parameters, so that a method of parameter identification is needed.

Indirect calculation method can approximately calculate the hot spot temperature of the winding of the transformer, and can basically reflect the actual heat transferring process. However, the reflection is insufficient. It has not covered all of the important factors of hot spot temperature distribution of the winding of the transformer. On the other hand, many parameters in the formulas are derived from the experience, which is not so universal and can impact the precision results. The thermal simulation measurement method can only solve the value of the hot spot temperature, but cannot help to judge the exact location of the hot spots.

Direct Measurement Method

According to the direct measurement method, a temperature sensor is installed near to a wire or a wire-line cake to measure the hot spot temperature of the winding directly. The sensor can be an audio sensor, a quartz crystal sensor, a fluorescent sensor, an infrared radiation excitation type sensor or a gallium arsenide compound crystal grains photoluminescent sensor, et al. Embedding method can be a method of embedding the sensors at duct gaps by a multiple-point distribution, just a method of embedding the sensors to an outlet of a wire-line cake gap, et al. The direct detection for the temperature of the transformer cannot adopt a conventional electrical sensor temperature measuring system. The infrared optical temperature measurement system can only be used to measure the surface temperature of an object, and cannot be used to measure the inner temperature of transformers of a complex structure. A fiber temperature sensor has a good electrical insulation capability, a strong anti-electromagnetic interference capability and an excellent reliability, and thus is ideal for measuring the temperature inside the transformer.

To obtain the entire temperature information of a certain span, it is a waste of resources and also is difficult to use a single point mobile sensing method or a quasi-distributed sensing method which is composed of a plurality of single points. In this case, applying a distributed fiber temperature sensor is clearly the most effective way.

In the method of adopting distributed fiber temperature sensors, the fibers are often arranged along a temperature field, by means of optical time domain reflect (abbreviation: OTDR) during the transferring of the light, the temperature is measured according to the temperature data carried by the scattered light beams. Currently, the most influential distributed fiber optic temperature sensor system based on the scattering mechanism comprises of: an optical time domain reflectometer measurement system based on Rayleigh scattering (Rayliegh-OTDR), an optical time domain reflectometer measurement system based on fiber Raman scattering (Raman-OTDR) and an optical time domain reflectometer measurement system based on Brillouin scattering (DOTDR-Brillouin OTDR).

From the current research result, the measurement error of the distributed fiber temperature measurement system is generally a few degrees Celsius, the positioning error thereof is about one meter. In the power system, the distributed fiber temperature measurement system is mainly used in monitoring the temperature distribution of cables. For monitoring the internal temperature of the transformer, the positioning error is clearly large. If the positioning accuracy is improved, the resolution to the temperature will reduce, so the using of this kind of temperature monitoring system on monitoring the internal temperature of transformers needs to be further researched.

A fiber bragg grating (FBG) sensor, which is developed rapidly in recent years, provides us a new temperature monitoring system because of its special structure. Use of fiber grating temperature measurement system belongs to a method of quasi-distributed temperature measurement, the method utilizes the photosensitiveness of fiber materials to measure temperature by spatial phase grating formed in the fiber core. In the sensing process, the information is accessed by modulating bragg grating center wavelength through the external parameters. It is a wavelength modulation type fiber sensor, which has a very good reliability and stability. FBG sensing system connects a plurality of FBG sensors in series to a fiber. The operation wavelength of each grating is different from others. After a 3dB coupler is used to pick out the reflected light, a wavelength demodulation system is used to simultaneously measure the wavelengths offsets of multiple gratings, thereby detection of the corresponding measured value and spatial distribution is achieved. When the broadband light source projects light beams to the fiber, each fiber grating reflects back narrowband light waves of a different bragg wavelength. Any incentive effect to the fiber grating, such as temperature or strain, will lead to the change of bragg wavelength of the fiber grating. Distributed fiber grating demodulation system measures the change of parameters of each test point by measuring the fine change of the wavelengths of reflected light beams from the fiber grating sensors at each test point.

In addition to the inherent advantages, such as anti-electromagnetic interference, high sensitivity, small size, easy embedding, easy to use multiplexing techniques to achieve the single-fiber-multi-point and multi-parameter quasi-distributed measurements, the quasi-distributed sensing fiber-optic temperature monitoring system also has the following advantages:.

(a) A large amount of information. The quasi-distributed sensing fiber-optic monitoring system can sense the change of the measured parameters along the length direction of the fiber in the form of a continuous function of the distance along the length of the entire continuous fiber. That is to say, any point of the fiber is a “sensor” and can contain a massive amount of information.

(b) A simple structure and a high reliability. Since the fiber-optic bus of the quasi-distributed sensing fiber-optic monitoring system not only plays a role of transmitting light but also plays a role of sensing, so its structure is very simple and it is easy to construct. There are less potential failures, a good maintainability, and a high reliability.

(c) Easy to use. After the fiber is embedded, the measuring points can be set as required. For example, the operator can set a measuring point every 2m or every lm. Therefore, it is extremely convenient to monitor the location of disease.

Thus, the present invention provides a method for predicting the life of a transformer based on a fiber grating temperature measurement system, so as to meet the actual needs.

### SUMMARY OF THE PRESENT INVENTION

The invention is advantageous in that it provides a method for predicting the life of a transformer based on a fiber grating temperature measurement system for overcoming the deficiencies of the prior art.

Additional advantages and features of the invention will become apparent from the description which follows, and may be realized by means of the instrumentalities and combinations particular point out in the appended claims.

According to the present invention, the foregoing and other objects and advantages are attained by a method for predicting the life of a transformer based on a fiber grating temperature measurement system comprising the following steps.

1) Provide a fiber grating temperature measurement system, wherein the fiber grating temperature measurement system comprises a transformer body, a terminal PC, a wavelength demodulator, a plurality of fiber grating sensors arranged inside the transformer body, and a wavelength demodulator comprising a broadband light source, a 3 dB coupler, an optical switch, a FP filter, a photoelectric conversion module, a sawtooth generator and a plurality of fibers; wherein in an operation process using the fiber grating temperature measurement system, light beams emitted by the broadband light source pass through the 3 dB coupler and then pass through the optical switch and then reach to each the fiber; each of the fibers is connected with the plurality of fiber grating sensors in series each having a different central reflection wavelength; wherein broadband light beams are reflected back as narrowband light beams of different peak wavelengths after projecting on each of the fiber grating sensors , and then the narrowband light beams enter into the FP filter and the photoelectric conversion module through the optical switch and the 3 dB coupler, so as to convert wavelength-encoded sensor signals into digital signals, and then the digital signals are send to the terminal PC for operation; wherein an internal temperature of the transformer body changes when the transformer body is working, and results in a change of to reflection wavelength of the fiber grating sensors; wherein at the same time, a single chip processor of the sawtooth generator provides a sawtooth voltage to a piezoelectric ceramics and changes a cavity length of the FP filter, so as to match with a wavelength of light beams passed through the FP filter; wherein when a wavelength of reflected light beams from the FP filter equals to a wavelength of reflected light beams from the fiber grating sensors, a photodetector outputs a maximum value, and a sweep voltage value of the piezoelectric ceramic is recorded; wherein a value of a scanning voltage and the wavelength of reflected light beams from the fiber grating at that time constitute a data pair; wherein according to a relationship of wavelength and temperature, after a change of wavelength is measured, a relative change of temperature is obtained, so as to achieve a purpose of temperature testing.

2) Record locations of the fiber grating sensors during an arrangement process of the fiber grating temperature measurement system; wherein according to “GB 1094.7-2008 Power transformer—Part 7: guide rules for load of oil-immersed power transformers”, a six-degree principle is used to calculate an insulation aging rate in the transformer and to obtain a life loss thereof; wherein due to an influence on an operation of the transformer by insulation aging in different locations of an internal of the transformer are different, the life loss is corrected with respect to an internal insulation location of the transformer, so as to calculate the life loss of the transformer.

A relationship between aging rate and temperature is shown in the following table:

| | | Insulation of thermal |
|---|---|---|
| | Insulation of non-thermal-modified | modified |
| θₕ (° C.) | paper (V) | paper (V) |
| 80 | 0.125 | 0.036 |
| 86 | 0.25 | 0.073 |
| 92 | 0.5 | 0.145 |
| 98 | 1.0 | 0.282 |
| 104 | 2.0 | 0.536 |
| 110 | 4.0 | 1.0 |
| 116 | 8.0 | 1.83 |
| 122 | 16.0 | 3.29 |
| 128 | 32.0 | 5.8 |
| 134 | 64.0 | 10.1 |
| 140 | 128.0 | 17.2 |

During a certain period, the life loss of the transformer is L:

$$L = {\int }_{t 1}^{t 2} V d t , or L = {\sum }_{n = 1}^{N} {V}_{n} \times {t}_{n} ;$$

Vₙ: relative aging rate of the n-th time interval:

t₀: a n-th time interval;

n: an ordinal number of each time interval during the time being considered;

N: a number of time interval of the time being considered; wherein the life loss of is transformer is:

L′=max kL;

Wherein a value of “k” is selected from the following table:

| | | | | | entrance | |
|---|---|---|---|---|---|---|
| position | leading wire | coil | iron core | oil duct | of cooler | top oil |
| k value | 0.9 | 0.95 | 0.95 | 0.98 | 0.99 | 1 |

A pointed assessment about an internal insulation aging degree of the transformer is given through this system, wherein based on a position of an internal partial insulation, an influence of the insulation aging degree at the position on the transformer is capable of being judged, so as to describe a life of the transformer scientifically and effectively.

The advantages of the present invention are as follows: the method according to the present invention is able to utilize a fiber grating temperature measuring system to calculate and evaluate the life loss of insulation in the inner side of the transformer and the changing rate thereof, so as to direct the operation and maintenance department for scientifically, safely and reliably improve the operation and maintenance strategies to the transformer. Through this system, the insulation aging degree in the transformer can be specifically assessed to the point. Based on the internal partial insulation position, the influence on the transformer of the insulation aging degree at the position is able to be judged, so as to scientifically and effectively describe the life of the transformer. Still further objects and advantages will become apparent from a consideration of the ensuing description and drawings.

These and other objectives, features, and advantages of the present invention will become apparent from the following detailed description, the accompanying drawings, and the appended claims.

### BRIEF DESCRIPTION OF THE DRAWINGS

FIG. 1 is a schematic diagram of a fiber grating temperature measurement system according to a preferred embodiment of the present invention.

### DETAILED DESCRIPTION OF THE PREFERRED EMBODIMENT

The following description is disclosed to enable any person skilled in the art to make and use the present invention. Preferred embodiments are provided in the following description only as examples and modifications will be apparent to those skilled in the art. The general principles defined in the following description would be applied to other embodiments, alternatives, modifications, equivalents, and applications without departing from the spirit and scope of the present invention.

The reference characters in the drawings are illustrated as follows: 1—transformer body; 2—personal computer; 3—wavelength demodulator; 4—FBG sensors; 5—broadband light source; 6-3 dB coupler; 7—optical switch; 8—FP cavity; 9—photoelectric conversion module (photoelectric detection signal amplification); 10—sawtooth generator; 11—optical fiber.

The present invention adopts a fiber grating temperature measurement system to provide a quasi-distributed description of the internal temperature of the transformer, and determines the position of the hottest spot inside the transformer. In accordance with “GB 1094.7-2008 Power transformer—Part 7: guide rules for load of oil-immersed power transformers”, conduct a life evaluation on an internal local region of the transformer; and according to the life loss of each position of the transformer, by combining the insulation characteristic of the transformer with the influence of the life of the position on the entire life of the transformer, predict the life of the transformer scientifically and reasonably. The following description will describe the present invention in details.

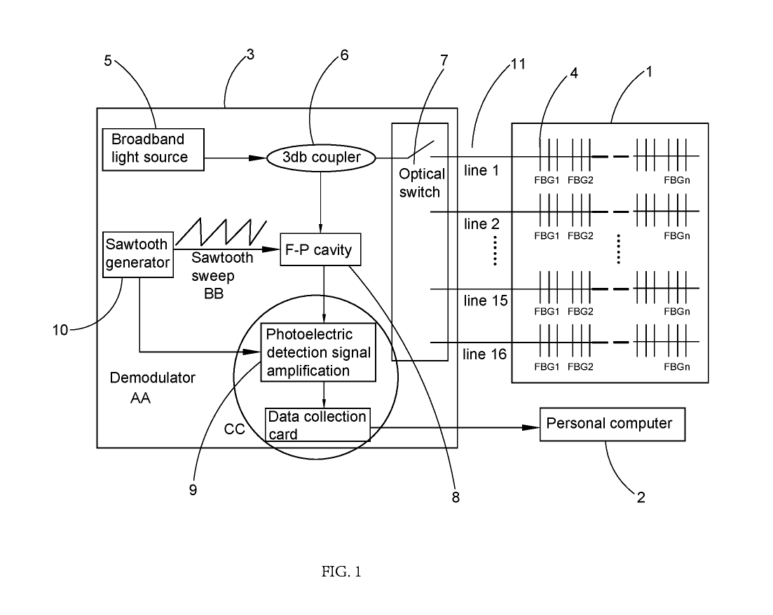

The structure of the fiber grating temperature measurement system is shown in FIG. 1 of the drawings. The system comprises a transformer body 1, a terminal PC 2, a wavelength demodulator 3 and a plurality of fiber grating sensors 4 arranged inside the transformer body 1, wherein the wavelength demodulator 3 comprises a broadband light source 5, a 3 dB coupler 6, an optical switch 7, a FP filter 8, a photoelectric conversion module 9, a sawtooth generator 10 and a plurality of fibers 11.

1. Fiber Grating Temperature Measurement System

Light beams emitted by the broadband light source 5 pass through the 3 dB coupler 6, and then pass through the optical switch 7, and then reach to each fiber 11. Each fiber 11 is connected with a plurality of different fiber grating sensors 4 in series each having a different central reflection wavelength, broadband light beams will be reflected back as narrowband light beams of different peak wavelengths after projecting on each of the fiber grating sensors 4, and then the narrowband light beams enter into the FP filter 8 and the photoelectric conversion module 9 through the optical switch 7 and the 3 dB coupler 6, so as to convert wavelength-encoded sensor signals into digital signals, and then send the digital signals to the terminal PC 2 for operation. The internal temperature of the transformer body 1 will change when the transformer body 1 is working, and will result in a change of the reflection wavelength of the inner fiber grating sensors 4. At the same time, a single chip processor of the sawtooth generator 10 provides a sawtooth voltage to a piezoelectric ceramics and change the cavity length of the FP filter 8, so as to match with the wavelength of light beams passed through the FP filter 8, wherein when the wavelength of the reflected light beams from the FP filter 8 equals to the wavelength of the reflected light beams from the fiber grating sensors 4, a photodetector outputs a maximum value, and a sweep voltage value of the piezoelectric ceramic is recorded, wherein the value of the scanning voltage and the wavelength of reflected light beams from the fiber grating at that time constitute a data pair. According to the relationship of the wavelength and the temperature, after the change of the wavelength is measured, the relative change of the temperature can be obtained, so as to achieve the purpose of temperature testing.

2. Life Prediction System

Record locations of the fiber grating sensors during an arrangement of the fiber grating temperature measurement system. According to “GB 1094.7-2008 Power transformer—Part 7: guide rules for load of oil-immersed power transformers”, a six-degree principle can be used to calculate the insulation aging rate in the transformer and obtain the life loss thereof. Due to the influence on the operation of the transformer by the insulation aging in different locations of the internal of the transformer are different, the life loss needs to be corrected with respect to the internal insulation location of the transformer, so as to calculate the life loss of the transformer.

The relationship between the aging rate and the temperature is shown in the following table:

| | | Insulation of thermal |
|---|---|---|
| | Insulation of non-thermal-modified | modified |
| θₕ (° C.) | paper (V) | paper (V) |
| 80 | 0.125 | 0.036 |
| 86 | 0.25 | 0.073 |
| 92 | 0.5 | 0.145 |
| 98 | 1.0 | 0.282 |
| 104 | 2.0 | 0.536 |
| 110 | 4.0 | 1.0 |
| 116 | 8.0 | 1.83 |
| 122 | 16.0 | 3.29 |
| 128 | 32.0 | 5.8 |
| 134 | 64.0 | 10.1 |
| 140 | 128.0 | 17.2 |

wherein during a certain period, the life loss of the transformer is L:

$$L = {\int }_{t 1}^{t 2} V d t , or L = {\sum }_{n = 1}^{N} {V}_{n} \times {t}_{n}$$

Wherein,

Vₙ: relative aging rate of the n-th time interval:

t₀: the n-th time interval;

n: ordinal number of each time interval during the time being considered;

N: number of time interval of the time being considered;

wherein the loss of life of the transformer is:

L′=max kL

Wherein the value of “k” is selected from the following table:

| | | | | | entrance | |
|---|---|---|---|---|---|---|
| position | leading wire | coil | iron core | oil duct | of cooler | top oil |
| k value | 0.9 | 0.95 | 0.95 | 0.98 | 0.99 | 1 |

A pointed assessment about the internal insulation aging degree of the transformer can be given through this system. Based on a position of an internal partial insulation, an influence of the insulation aging degree at that position on the transformer is capable of being judged, so as to describe the life of the transformer scientifically and effectively.

One skilled in the art will understand that the embodiment of the present invention as shown in the drawings and described above is exemplary only and not intended to be limiting.

It will thus be seen that the objects of the present invention have been fully and effectively accomplished. The embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A method for predicting the life of a transformer based on a fiber grating temperature measurement system, comprising the following steps:
1) providing a fiber grating temperature measurement system, wherein said fiber grating temperature measurement system comprises a transformer body, a terminal PC, a wavelength demodulator, a plurality of fiber grating sensors arranged inside said transformer body, and a wavelength demodulator comprising a broadband light source, a 3 dB coupler, an optical switch, a FP filter, a photoelectric conversion module, a sawtooth generator and a plurality of fibers; wherein in an operation process using said fiber grating temperature measurement system, light beams emitted by said broadband light source pass through said 3 dB coupler and then pass through said optical switch and then reach to each said fiber; each of said fibers is connected with said plurality of fiber grating sensors in series each having a different central reflection wavelength; wherein broadband light beams are reflected back as narrowband light beams of different peak wavelengths after projecting on each of the fiber grating sensors, and then said narrowband light beams enter into said FP filter and said photoelectric conversion module through said optical switch and said 3 dB coupler, so as to convert wavelength-encoded sensor signals into digital signals, and then said digital signals are send to said terminal PC for operation; wherein an internal temperature of said transformer body changes when said transformer body is working, and results in a change of to reflection wavelength of said fiber grating sensors; wherein at the same time, a single chip processor of said sawtooth generator provides a sawtooth voltage to a piezoelectric ceramics and changes a cavity length of said FP filter, so as to match with a wavelength of light beams passed through said FP filter; wherein when a wavelength of reflected light beams from said FP filter equals to a wavelength of reflected light beams from said fiber grating sensors, a photodetector outputs a maximum value, and a sweep voltage value of said piezoelectric ceramic is recorded; wherein a value of a scanning voltage and said wavelength of reflected light beams from said fiber grating at that time constitute a data pair; wherein according to a relationship of wavelength and temperature, after a change of wavelength is measured, a relative change of temperature is obtained, so as to achieve a purpose of temperature testing; and
2) recording locations of said fiber grating sensors during an arrangement process of said fiber grating temperature measurement system; wherein according to “GB 1094.7-2008 Power transformer—Part 7: guide rules for load of oil-immersed power transformers”, a six-degree principle is used to calculate an insulation aging rate in said transformer and to obtain a life loss thereof; wherein due to an influence on an operation of said transformer by insulation aging in different locations of an internal of said transformer are different, said life loss is corrected with respect to an internal insulation location of said transformer, so as to calculate said life loss of said transformer;
wherein a relationship between aging rate and temperature is shown in the following table:

| | | Insulation of thermal |
|---|---|---|
| | Insulation of non-thermal-modified | modified |
| θₕ (° C.) | paper (V) | paper (V) |
| 80 | 0.125 | 0.036 |
| 86 | 0.25 | 0.073 |
| 92 | 0.5 | 0.145 |
| 98 | 1.0 | 0.282 |
| 104 | 2.0 | 0.536 |
| 110 | 4.0 | 1.0 |
| 116 | 8.0 | 1.83 |
| 122 | 16.0 | 3.29 |
| 128 | 32.0 | 5.8 |
| 134 | 64.0 | 10.1 |
| 140 | 128.0 | 17.2 |

wherein during a certain period, said life loss of said transformer is L:
$$L = {\int }_{t 1}^{t 2} V d t , or L = {\sum }_{n = 1}^{N} {V}_{n} \times {t}_{n} ;$$
Wherein,
Vₙ: relative aging rate of the n-th time interval:
tₙ: a n-th time interval;
n: an ordinal number of each time interval during the time being considered;
N: a number of time interval of the time being considered;
wherein said life loss of is transformer is:
L′=max kL;
Wherein a value of “k” is selected from the following table:

| | leading | | iron | | | |
|---|---|---|---|---|---|---|
| position | wire | coil | core | oil duct | entrance of cooler | top oil |
| k value | 0.9 | 0.95 | 0.95 | 0.98 | 0.99 | 1 |

wherein a pointed assessment about an internal insulation aging degree of said transformer is given through this system, wherein based on a position of an internal partial insulation, an influence of said insulation aging degree at said position on said transformer is capable of being judged, so as to describe a life of said transformer scientifically and effectively.
